(19) United States
(12) Patent Application Publication
(10) Pub. No.: US 2013/0049543 A1
(43) Pub. Date: Feb. 28, 2013

(54) CRYSTAL RESONATOR

(71) Applicants: YOSHIAKI AMANO, SAITAMA (JP); RYOICHI ICHIKAWA, SAITAMA (JP)

(72) Inventors: YOSHIAKI AMANO, SAITAMA (JP); RYOICHI ICHIKAWA, SAITAMA (JP)

(73) Assignee: NIHON DEMPA KOGYO CO., LTD., TOKYO (JP)

(21) Appl. No.: 13/584,834

(22) Filed: Aug. 14, 2012

(30) Foreign Application Priority Data
Aug. 30, 2011 (JP) 2011-187655

(51) Int. Cl. H01L 41/053

(52) U.S. Cl. 310/344

(57) ABSTRACT

Disclosed is a crystal resonator including: a first plate having a first face and a second face opposite to the first face; a second plate having a third face and a fourth face opposite to the third face; a bonding material arranged in a ring shape between the second face of the first plate and the third face of the second plate to bond the first and second plates; a first trench portion, where the bonding material intrudes along a ring shape of the bonding material, on at least one of the second or third face; and a second trench portion formed side by side with the first trench portion in an inner side of the ring shape of the bonding material on at least one of the second face or the third face.

### CROSS REFERENCE TO RELATED APPLICATIONS

This application claims the priority benefit of Japan application serial no. 2011-187655, filed on Aug. 30, 2011. The entirety of the above-mentioned patent application is hereby incorporated by reference herein and made a part of this specification.

### TECHNICAL FIELD

This disclosure relates to a surface-mounted crystal resonator, and more particularly, to a crystal resonator in which first and second plates are encapsulated using an encapsulating material.

### DESCRIPTION OF THE RELATED ART

In a surface-mounted crystal resonator, a crystal resonating piece is stored in an insulative base plate made of glass, ceramic, and the like. The insulative base plate is encapsulated with a lid plate. There have been proposed a variety of manufacturing methods of encapsulating the lid plate.

Patent Literature 1 discloses a method of manufacturing a crystal resonator. In this technique, a ceramic package includes a metal seal ring. A metal lid plate is placed on the seal ring, and the lid plate is encapsulated through brazing. The seal ring is provided with a concave trench in order to retain a sufficient amount of the brazing material and enhance a bonding strength.

Patent Literature 2 discloses another method of manufacturing a crystal resonator. In this technique, an encapsulating material made of low-melting glass is printed on both bonding faces of the base plate and the lid plate. In addition, the base plate and the lid plate overlap with each other, and they are heated and pressed so that the base plate and the lid plate are encapsulated with low-melting glass.
[Patent Literature 1] Japanese Patent Application Laid-open No. 2001-148436
[Patent Literature 2] Japanese Patent Application Laid-open No. 2004-297372

However, as the crystal resonator is miniaturized, a width of the bonding face of the base plate or the lid plate and a width of the encapsulating material are also narrowed. For this reason, a leakage of gas or vapor is easily generated from an outer side of the crystal resonator to a cavity or from the cavity to the outer side of the crystal resonator, and the bonding strength is also degraded. Meanwhile, if the base plate and the lid plate are bonded by increasing the amount of the encapsulating material in order to enhance the bonding strength, an excess encapsulating material enters the cavity, which is problematic.

Thus, needs for a crystal resonator capable of suppressing the encapsulating material from entering the inside of the cavity, enhancing the bonding strength, and improving an impact resistance are existed.

### SUMMARY

According to a first aspect of the disclosure, there is provided a crystal resonator including: a first plate having a first face and a second face opposite to the first face; a second plate having a third face and a fourth face opposite to the third face; a bonding material arranged in a ring shape between the second face of the first plate and the third face of the second plate to bond the first and second plates; a first trench portion, where the bonding material intrudes along a ring shape of the bonding material, on at least one of the second or third face; and a second trench portion formed side by side with the first trench portion in an inner side of the ring shape of the bonding material on at least one of the second face or the third face.

According to a second aspect of the crystal resonator, there is provided a crystal resonator including: a first plate having a first face and a second face opposite to the first face; a second plate having a third face and a fourth face opposite to the third face; a bonding material arranged in a ring shape between the second face of the first plate and the third face of the second plate to bond the first plate and the second plate; a first trench portion, where the bonding material intrudes along a ring shape of the bonding material, on at least one of the second or third face; at least a pair of castellated portions formed at a corner of at least one of the first or second plate; and a third trench portion connecting from the first trench portion to the castellated portion.

### BRIEF DESCRIPTION OF THE DRAWINGS

The foregoing and additional features and characteristics of this disclosure will become more apparent from the following detailed description considered with the reference to the accompanying drawings, wherein:

FIG. 1A is an exploded perspective view illustrating a first crystal resonator 100 according to a first embodiment of the disclosure;

FIG. 1B is a cross-sectional view taken along a line A-A′ for illustrating the first crystal resonator 100;

FIG. 2 is a flowchart illustrating a process of manufacturing the first crystal resonator 100 according to the first embodiment of the disclosure;

FIG. 3 is a top plan view illustrating a first wafer (base wafer) W40;

FIG. 4 is a top plan view illustrating a second wafer (lid wafer) W10;

FIGS. 5A to 5C is an explanatory diagram illustrating step S108 for bonding the first and second wafers W10 and W40 in detail;

FIG. 6A is a cross-sectional view illustrating the first crystal resonator 100A according to a first modification of the disclosure;

FIG. 6B is a cross-sectional view illustrating the first crystal resonator 100B according to a second modification of the disclosure;

FIG. 7A is an exploded perspective view illustrating a second crystal resonator 110 according to a second embodiment of the disclosure;

FIG. 7B is a cross-sectional view taken along a line B-B′ for illustrating the second crystal resonator 110;

FIG. 8 is a flowchart illustrating a process of manufacturing the second crystal resonator 110 according to the second embodiment of the disclosure;

FIG. 9A is an exploded perspective view illustrating a third crystal resonator 120 according to a third embodiment of the disclosure;

FIG. 9B is a cross-sectional view taken along a line C-C′ for illustrating the third crystal resonator 120;

FIG. 10 is an enlarged view illustrating the portion EL of FIG. 9B;

FIG. 11A is an exploded perspective view illustrating a fourth crystal resonator 130 according to a fourth embodiment of the disclosure;

FIG. 11B is a cross-sectional view taken along a line D-D′ for illustrating the fourth crystal resonator 130; and

FIG. 12 is a top plan view illustrating the crystal wafer W32.

### DETAILED DESCRIPTION

### First Embodiment

### <Entire Configuration of First Crystal Resonator 100>

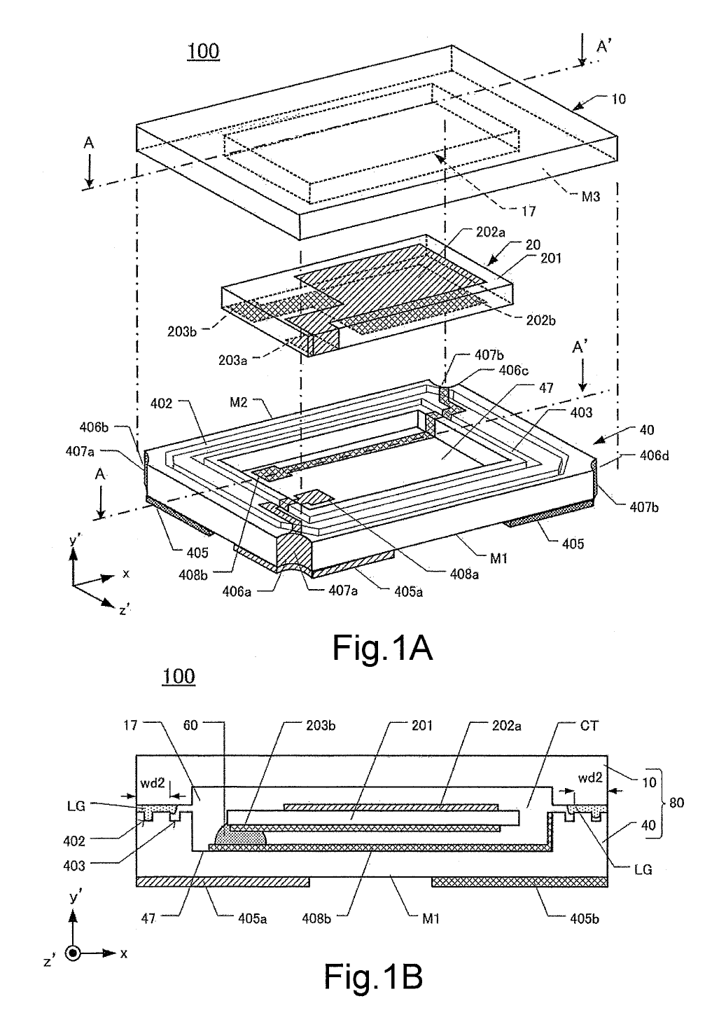

The entire configuration of the first crystal resonator will be described with reference to FIGS. 1A, 1B, FIGS. 2-4 and FIGS. 5A-5C.

The first crystal resonator 100 includes a first lid plate 10 having a lid hollow portion 17, a first base plate 40 having a base hollow portion 47, and a first crystal resonating piece 20 placed on the first base plate 40 as illustrated in FIGS. 1A and 1B. In the first crystal resonator 100, the first lid plate 10 and the first base plate 40 are bonded to each other to form a package 80 (refer to FIG. 1B). Inside the package 80, a cavity CT is formed (refer to FIG. 1B), and the first crystal resonating piece 20 is placed in the cavity CT.

According to the first embodiment of the disclosure, an AT-cut first crystal resonating piece 20 is used as the crystal resonating piece. The AT-cut crystal resonating piece has a principal face (YZ plane) passing through the X-axis and inclined by 35° 15′ from the Z-axis in the Y-axis direction of the crystal axes in the XYZ coordinate system. For this reason, according to the first embodiment of the disclosure, y′ and z′ axes inclined with respect to the axis direction of the AT-cut crystal resonating piece are newly defined. Specifically, according to the first embodiment of the disclosure, the longitudinal direction of the first crystal resonator 100 is defined as x-axis direction, the height direction of the first crystal resonator 100 is defined as a y′-axis direction, a direction perpendicular to the x and y′ axes is defined as a z′-axis direction. The aforementioned definition will be similarly applied to the second to fourth embodiments described below.

The first crystal resonating piece 20 includes an AT-cut crystal piece 201. A pair of excitation electrodes 202a and 202b is oppositely arranged on both principal faces in the vicinity of the center of the crystal piece 201. In addition, a lead electrode 203a extending up to the −x side of the bottom face (−y′ side) of the crystal piece 201 is connected to the excitation electrode 202a. A lead electrode 203b extending up to the +x side of the bottom face (−y′ side) of the crystal piece 201 is connected to the excitation electrode 202b. Furthermore, the excitation electrodes 202 and the lead electrodes 203 are formed, for example, by using a chrome layer as a base and using a gold layer on top of the chrome layer.

The first base plate 40 is made of crystal, borate glass, or the like. The first base plate 40 includes a base hollow portion 47 in the +y′ side of the first base plate 40 and a first face M2 formed around the base hollow portion 47. The base hollow portion 47 has connecting electrodes 408a and 408b in the −x side of the bottom face.

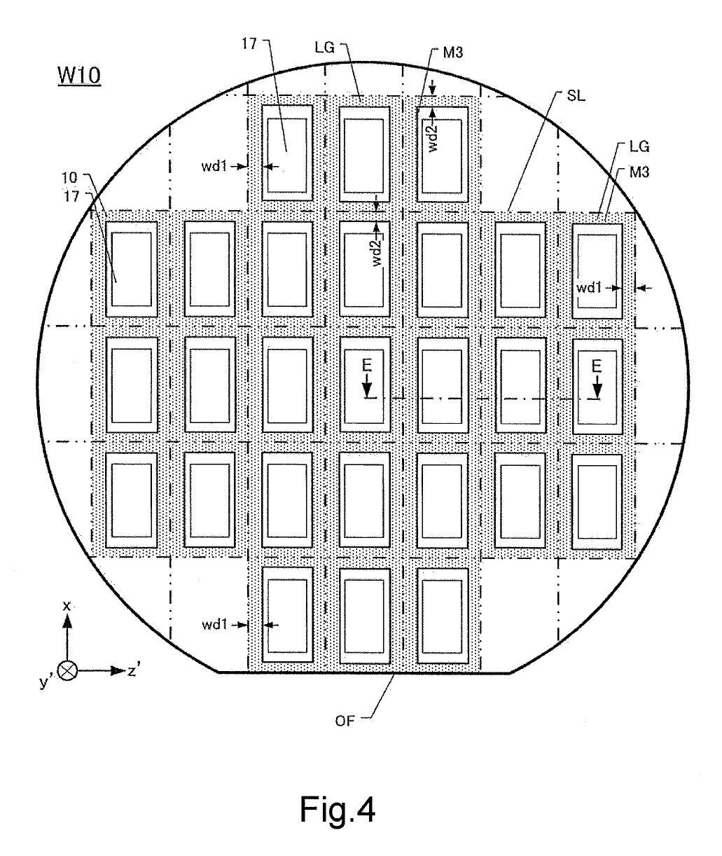

Castellated portion 406a, 406b, 406c, and 406d are formed at four corners of the first base plate 40 by dicing the circular through-hole BH1 (refer to FIG. 4). Lateral electrodes 407a and 407b are formed in the base plate castellated portions 406a and 406c, respectively. In addition, the connecting electrode 408a electrically connected to the lateral electrode 407a is formed in the −x side of the first bonding face M2 of the first base plate 40. Similarly, the connecting electrode 408b electrically connected to the lateral electrode 407b is formed in the +x side of the first bonding face M2 of the first base plate 40.

First and second base trench portions 402 and 403 are formed in the first bonding face M2 of the first base plate 40 to surround the base hollow portion 47 in a frame shape. The first and second base trench portions 402 and 403 are formed side by side. In addition, the first base plate 40 has a pair of mounting terminals 405a and 405b electrically connected to the lateral electrodes 407a and 407b, respectively, on the mounting face M1 (refer to FIG. 1B).

The first lid plate 10 is made of crystal, borate glass, or the like. The first lid plate 10 includes a lid hollow portion 17 in the −y′ side face and a second bonding face M3 formed around the lid hollow portion 17. The lid hollow portion 17 and the base hollow portion 47 provide a cavity CT for storing the first crystal resonating piece 20. The first crystal resonating piece 20 is placed on the connecting electrodes 408a and 408b of the first base plate 40 and is electrically connected to the mounting terminals 405a and 405b by interposing the conductive adhesive 60. The cavity CT is filled with an inert gas or hermetically sealed in vacuum.

An encapsulating material LG of low-melting glass is arranged between the first bonding face M2 of the first base plate 40 and the second bonding face M3 of the first lid plate 10. The encapsulating material LG is used to bond the first base plate 40 and the first lid plate 10.

The encapsulating material LG of low-melting glass includes lead-free vanadium-based glass melting at a temperature of 350° C. to 400° C. The vanadium-based glass is a nonconductive adhesive and in the form of a paste where a binder and a solvent are added, and is molten and then solidified so as to adhere to other elements. A melting point of the vanadium-based glass is lower than the melting point of the first lid plate 10 or the first base plate 40 formed of crystal, glass, or the like. The vanadium-based glass is highly reliable in a hermetic sealability, a waterproof property, a resistance to dampness, and the like when it is bonded.

FIG. 1B is a cross-sectional view taken along a line A-A′ of FIG. 1A. The second bonding face M3 of the first lid plate 10 and the first bonding face M2 of the first base plate 40 are bonded to each other by interposing the encapsulating material LG. In addition, the encapsulating material LG intrudes into the first base trench portion 402 at an outer side. Since the encapsulating material LG intrudes into the first base trench portion 402, it is possible to increase the sealing area and the bonding strength between the base plate 40 and the lid plate 10 by the encapsulating material LG. A small amount of the encapsulating material LG also intrudes into the second base trench portion 403 in the cavity (inner side). A package 80 is formed by bonding the first lid plate 10 and the first base plate 40. Before the first lid plate 10 and the first base plate 40 are bonded, the encapsulating material LG has a width wd2, and the encapsulating material LG does not overlap with the second base trench portion 403 in the Y′-axis direction.

The first crystal resonating piece 20 is placed in the cavity CT. The lead electrodes 203a and 203b of the first crystal resonating piece 20 are electrically connected to the connecting electrodes 408a and 408b, respectively, by interposing the conductive adhesive 60. In addition, the connecting electrodes 408a and 408b are electrically connected to the mounting terminals 405a and 405b, respectively, through the first base trench portion 402 and the second base trench portion 403 of the first base plate 40. That is, the excitation electrodes 202a and 202b of the first crystal resonating piece 20 are electrically connected to the mounting terminals 405a and 405b, respectively. If a voltage is applied between two mounting terminals 405a and 405b, the first crystal resonating piece 20 is vibrated.

<Method of Manufacturing First Crystal Resonator 100>

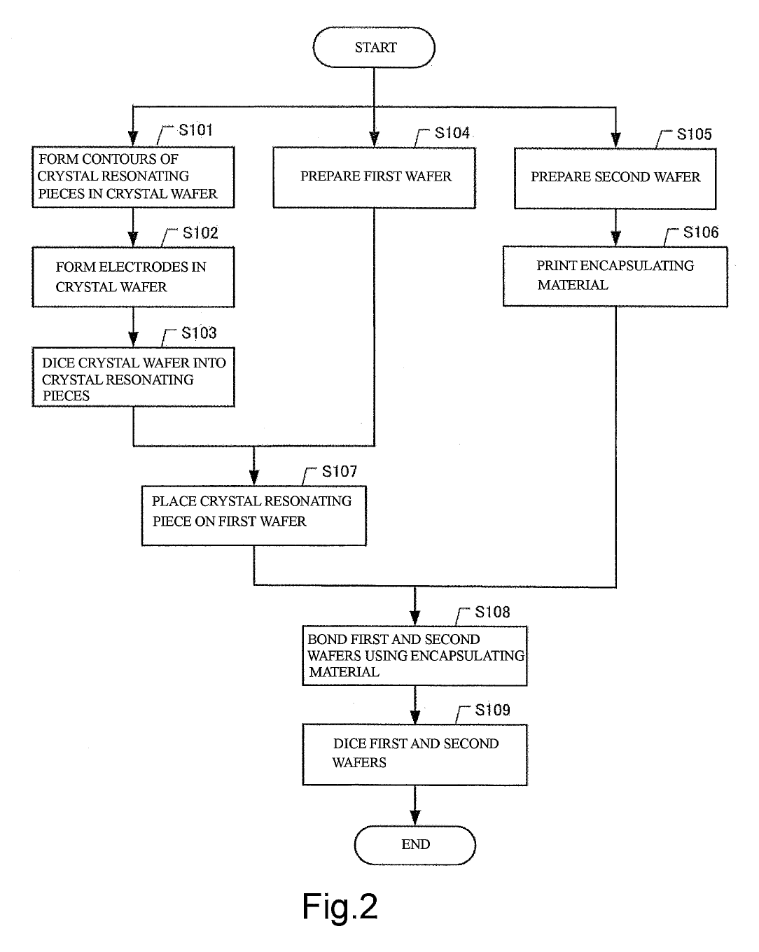

FIG. 2 is a flowchart illustrating a method of manufacturing the first crystal resonator 100.

In step S101, contours of a plurality of crystal resonating pieces 20 are formed in the crystal wafer.

In step S102, the excitation electrode 202 and the lead electrode 203 are formed in each crystal resonating piece 20 formed in the crystal wafer.

In step S103, individual crystal resonating pieces 20 are cut out from the crystal wafer.

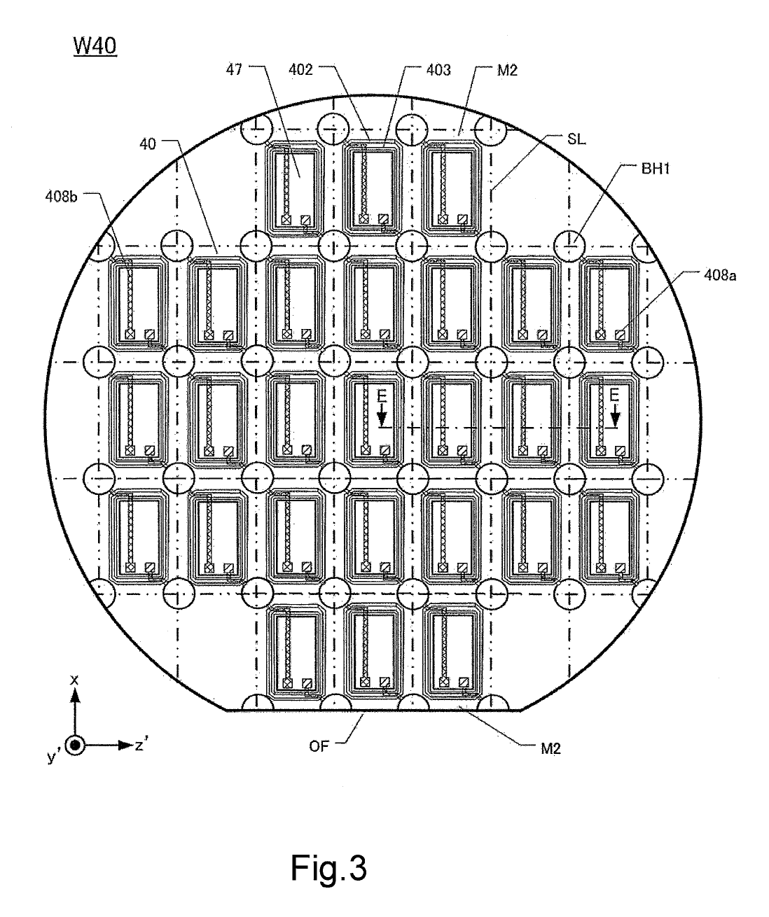

In step S104, the first wafer W40 is prepared. A plurality of first base plates 40 are formed in the first wafer W40. The first wafer W40 is formed of, for example, crystal, glass, or the like. The first wafer W40 will be described with reference to FIG. 3.

FIG. 3 is a top plan view illustrating the first wafer W40. A plurality of first base plates 40 are formed in the first wafer W40. The hollow portion 47 is formed in the +y′-axis side face of the first base plate 40. In addition, the connecting electrodes 408a and 408b are formed in the hollow portion 47. The first and second base trench portions 402 and 403 are formed in the second bonding face M2 around the hollow portion 47 to surround the hollow portion 47. In addition, the circular through-hole BH1 is formed in four corners of each of the first base plate 40.

In addition, although not illustrated in FIG. 3, the mounting terminal 405 is formed in the −y′-axis side face of the first wafer W40 (refer to FIG. 1B). In FIG. 3, the boundary between the neighboring first base plates 40 is indicated by a two-dot chain line. The two-dot chain line corresponds to the scribe line SL for dicing the first wafer in step S109 of FIG. 2.

In step S105, the second wafer W10 is prepared. A plurality of first lid plates 10 are formed in the second wafer W10. The second wafer W10 is formed of, for example, crystal, glass, or the like. The second wafer W10 will be described with reference to FIG. 4.

FIG. 4 is a top plan view illustrating the second wafer W10 as seen from the −y′-axis side to the +y′-axis direction. A plurality of first lid plates 10 are formed in the second wafer W10. In FIG. 4, the boundary between the neighboring first lid plates 10 is indicated by a two-dot chain line. The two-dot chain line corresponds to the scribe line for dicing the second wafer in step S109 of FIG. 2. The hollow portion 17 is formed in the −y′-axis side face of each first lid plate 10, and the second bonding face M3 is formed around the hollow portion 17.

In step S106, the encapsulating material LG is coated on the second bonding face M3. However, the encapsulating material LG is not coated on the entire surface of the second bonding face M3 except for the hollow portion 17. As illustrated in FIG. 4, in the z′-axis direction, the encapsulating material LG having a width wd1 is coated from a position apart from the hollow portion 17 by a predetermined distance to the scribe line SL. In the x-axis direction, the encapsulating material LG having a width wd2 is coated from a position apart from the hollow portion 17 by a predetermined distance to the scribe line SL. This causes the encapsulating material LG to overlap with the first base trench portion 402 and not to overlap with the second base trench portion 403 when the first wafer W40 and the second wafer W10 are overlapped. In addition, the widths wd1 and wd2 may be substantially equal.

In step S107, the first crystal resonating piece 20 is placed on the first wafer W40.

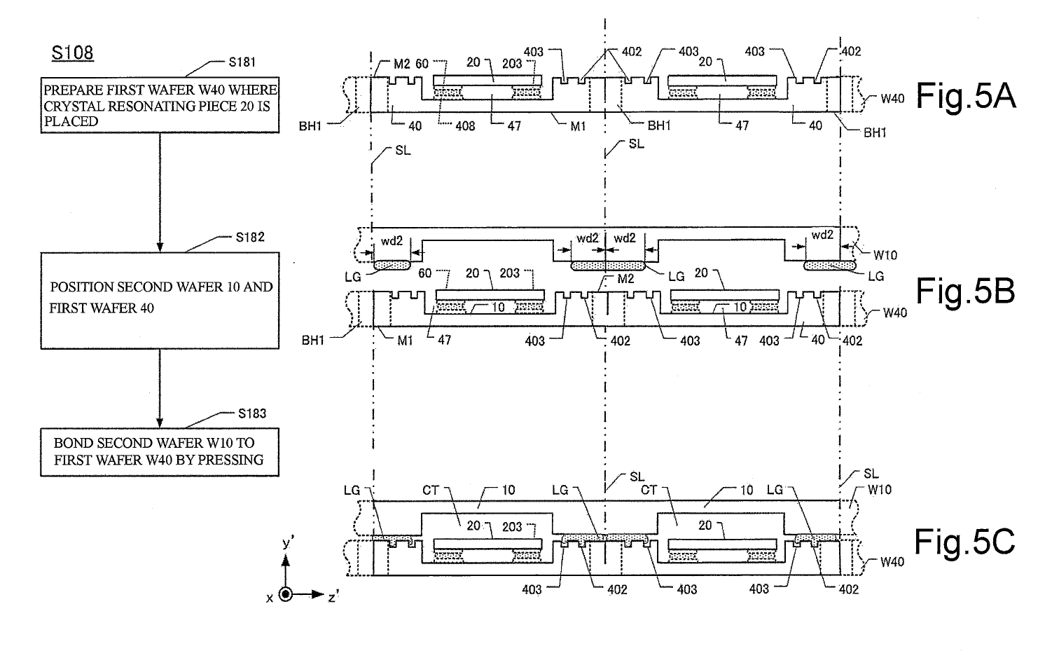

In step S108, the second wafer W10 and the first wafer W40 are bonded. Details of step S108 will be described below with reference to FIGS. 5A to 5C.

In step S109, the first wafer W40 and the second wafer W10 are diced along the scribe line SL. Through the dicing, the wafers are divided into individual first crystal resonators 100.

In FIGS. 5A to 5C, a flowchart for describing a process of bonding the second wafer W10 and the first wafer W40 in step S108 of FIG. 2 is illustrated. In addition, schematic cross-sectional views taken along a line E-E of FIG. 3 for describing each step are also illustrated in the right horizontal sides of each step. In FIGS. 5A to 5C, a boundary between the neighboring first base plates 40 is indicated by a two-dot chain line. The two-dot chain line corresponds to the scribe line SL.

In step S181, the first wafer W40 where the first crystal resonating piece 20 is placed (in step S107) is prepared. As illustrated in FIG. 5A, the first crystal resonating piece 20 is placed on the hollow portion 47 of the first base plate 40 formed in the first wafer W40. In this case, the lead electrode 203 of the first crystal resonating piece 20 is connected to the connecting electrode 408 by interposing the conductive adhesive 60.

In step S182, the second wafer W10 where the encapsulating material LG is formed is positioned on the first wafer W40. FIG. 5B illustrates a state before the second wafer W10 and the first wafer W40 are bonded. The scribe lines of the second wafer W10 and the first wafer W40 overlap with each other along the y′-axis direction. That is, the first bonding face M2 and the second bonding face M3 are positioned to overlap with each other. The encapsulating material LG is formed with a width wd2 in the x-axis direction of the second bonding face M3.

As illustrated in FIG. 5B, the encapsulating material LG formed in the second wafer W10 has a width wd2 from the scribe line SL. This width wd2 overlaps with the first base trench portion 402 formed in the first bonding face M2 of the first base plate 40, but does not overlap with the second base trench portion 403. That is, the width wd2 extends from the scribe line SL to immediately before the second base trench portion 403 of the first bonding face M2 at maximum.

In step S183, while the second wafer W10 and the first wafer W40 are heated, they are pressed in the y′-axis direction. FIG. 5C illustrates a state that the second wafer W10 and the first wafer W40 are bonded. The encapsulating material LG is interposed between the second wafer W10 and the first wafer W40 and intrudes into the first base trench portion 402. Further, the encapsulating material LG is widened in the +z′-axis direction and the −z′-axis direction. Out of the widened encapsulating material LG, a part of the encapsulating material LG widened to the cavity CT side enters into the second trench portion 403. The first base trench portion 402 increases the contact area of the encapsulating material LG with the first bonding face M2 of the first base plate 40, and thus, the bonding strength between the first lid plate 10 and the first base plate 40 increases. In addition, the first base trench portion 402 can suppress the encapsulating material LG from entering the inside of the cavity CT.

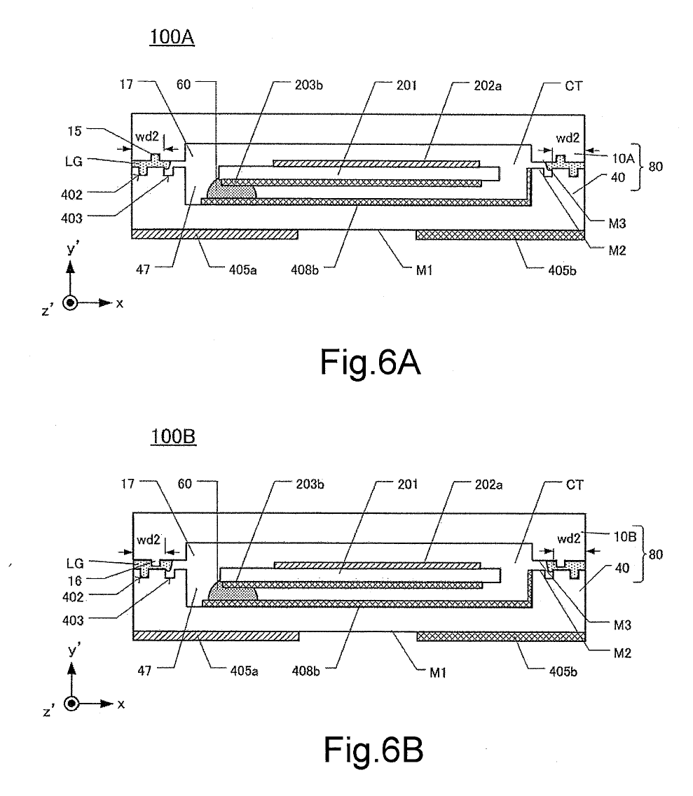

FIG. 6A is a cross-sectional view illustrating the crystal resonator 100A as a first modification of the first crystal resonator 100. FIG. 6B is a cross-sectional view illustrating the crystal resonator 100B as a second modification of the first crystal resonator 100.

As illustrated in FIG. 6A, the crystal resonator 100A has a lid plate 10A different from the first lid plate 10 (refer to FIGS. 1A and 1B). The lid plate 10A has a lid trench portion 15 having a frame shape in the second bonding face M3 thereof. Before the lid plate 10A and the first base plate 40 are bonded, the encapsulating material LG having a width wd2 is printed on the second bonding face M3 of the lid plate 10A. The lid trench portion 15 is positioned within the width wd2 of the encapsulating material LG.

The lid trench portion 15 and the first base trench portion 402 enhances the bonding strength between the base plate 40 and the lid plate 10A using the encapsulating material LG. In addition, when the base plate 40 and the lid plate 10A are bonded, they are pressed, and the encapsulating material LG is thinned and widened, so that a part of the widened encapsulating material LG intrudes into the second base trench portion 403. For this reason, the second base trench portion 403 suppresses the widened encapsulating material LG from entering the inside of the cavity CT.

As illustrated in FIG. 6B, the crystal resonator 100B has a lid plate 10B different from the first lid plate 10 (refer to FIGS. 1A and 1B). The lid plate 10B has a lid convex frame portion 16 in the second bonding face M3 thereof. Before the lid plate 10B and the first base plate 40 are bonded, the encapsulating material LG having a width wd2 is printed on the second bonding face M3 of the lid plate 10B. The lid convex frame portion 16 is positioned within a width wd2 of the encapsulating material LG. That is, the encapsulating material LG is printed on the lid convex frame portion 16 in an ingrowing manner.

In the lid convex frame portion 16 and the first base trench portion 402, the bonding strength between the lid plate 10B and the base plate 40 using the encapsulating material LG is enhanced by increasing the encapsulating area. In addition, when the base plate 40 and the lid plate 10B are bonded, they are pressed, and the encapsulating material LG is thinned and widened, so that a part of the widened encapsulating material LG intrudes into the second base trench portion 403. For this reason, the second base trench portion 403 suppresses the widened encapsulating material from entering the inside of the cavity CT.

### Second Embodiment

### <Entire Configuration of Second Crystal Resonator 110>

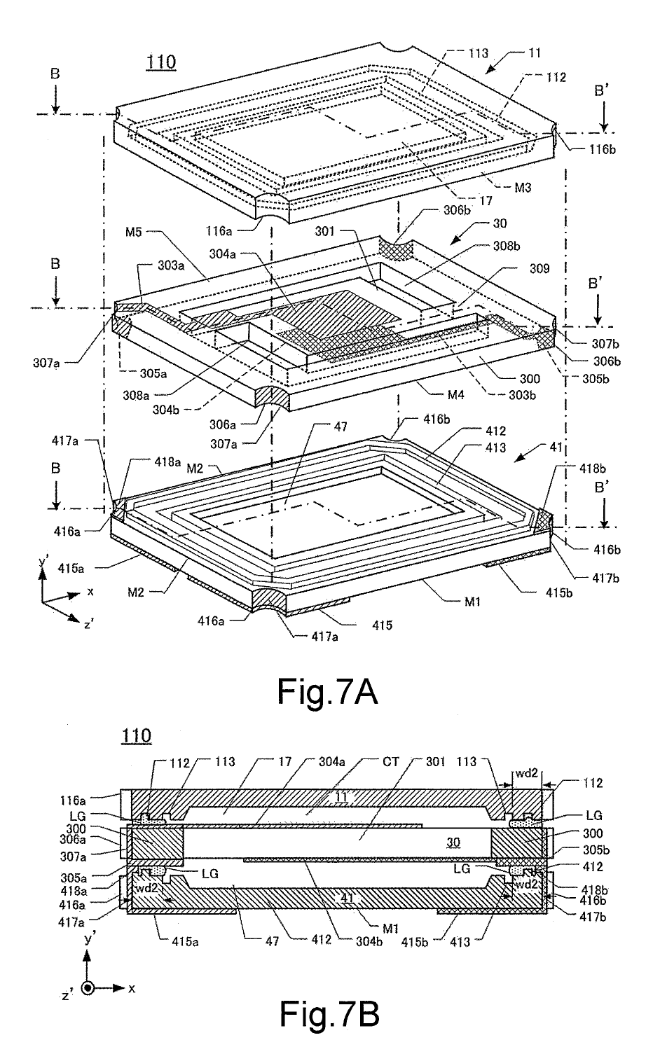

The second crystal resonator 110 according to the second embodiment of the disclosure includes a first crystal frame 30, a second base plate 41, and a second lid plate 11 as illustrated in FIGS. 7A and 7B. FIG. 7A is an exploded perspective view illustrating the second crystal resonator 110, and FIG. 7B is a cross-sectional view taken along a line B-B′ for illustrating the second crystal resonator 110.

The second crystal resonator 110 is different from the first crystal resonator 100 in that the first crystal frame 30 is mounted instead of the first crystal resonating piece 20 of the first crystal resonator 100. In addition, the frame-shaped convex portion 412 and the trench portion 413 are formed in the second base plate 41, and the first and second trench portions are formed in the second lid plate 11. In the second embodiment, like reference numerals denote like elements as in the first crystal resonator 100 of the first embodiment, and description thereof will not be repeated.

The second base plate 41 and the second lid plate 11 are made of a crystal material, glass, or the like. In addition, the first crystal frame 30 and the second base plate 41 are bonded using the encapsulating material LG, and the first crystal frame 30 and the second lid plate 11 are bonded using the encapsulating material LG.

The first crystal frame 30 includes a crystal bonding face M4 and a crystal bonding face M5. The first crystal frame 30 has an outer frame 300 surrounding the crystal piece 301. The gap portions 308a and 308b having a vertically penetrating L-shape are formed between the crystal piece 301 and the outer frame 300. The portion where the gap portions 308a and 308b are not formed corresponds to the connecting portion 309 between the crystal piece 301 and the outer frame 300.

The first crystal frame 30 includes the AT-cut crystal piece 301. A pair of excitation electrodes 304a and 304b is oppositely arranged in both principal faces in the vicinity of the center of the crystal piece 301. In addition, the connecting electrode pad 305a and the lead electrode 303a extending up to the −x end side of the bottom face (−y′) of the AT-cut crystal piece 301 are connected to the excitation electrode 304a. Furthermore, the connecting electrode pad 305b and the lead electrode 303b extending up to the +x side end of the bottom face (−y′) of the AT-cut crystal piece 301 are connected to the excitation electrode 304b. The connecting electrode pads 305a and 305b of the first crystal frame 30 are bonded to the connecting electrodes 408a and 408b, respectively, of the second base plate 41.

In addition, the excitation electrodes 304a and 304b and the conducted lead electrodes 305a and 305b are respectively formed on both faces of the outer frame 300. In addition, the crystal castellated portions 306a and 306b are formed in four corners of the first crystal frame 30. The crystal lateral electrodes 307a and 307b connected to the lead electrodes 305a and 305b, respectively, are formed in a pair of the crystal castellated portions 306a and 306b. The crystal castellated portions 306a and 306b are formed by dicing the circular through-hole.

The second lid plate 11 includes a lid hollow portion 17 in the −y′ side and a second bonding face M3 formed around the lid hollow portion 17. A second lid trench portion 113 having a frame shape along the lid hollow portion 17 is formed in the second bonding face M3, and a first lid trench portion 112 is formed at an outer side thereof. Castellated portions 116a and 116b are formed in four corners of the second lid plate 11.

The second base plate 41 has a base hollow portion 47 in the +y′ side and a bonding face M2 formed around the base hollow portion 47. The base hollow portion 47 has connecting electrodes 418a and 418b in the +y′ side of the bonding face M2.

Castellated portions 416a and 416b are formed in four corners of the second base plate 41 by dicing the circular through-hole BH1. The lateral electrodes 417a and 417b are formed in the castellated portions 416a and 416b, respectively. In addition, the connecting electrode 418a electrically connected to the lateral electrode 417a is formed in the −x side of the bonding face M2 of the second base plate 41. Similarly, the connecting electrode 418b electrically connected to the lateral electrode 417b is formed in the +x side of the bonding face M2 of the second base plate 41.

A second base trench portion 413 and a base convex frame portion 412 at an outer side thereof are formed in the bonding face M2 of the second base plate 41 to surround the base hollow portion 47 in a frame shape. In addition, the second base plate 41 has a pair of mounting terminals 415a and 415b electrically connected to the lateral electrodes 417a and 417b, respectively, in the mounting face M1.

FIG. 7B is a cross-sectional view taken along a line B-B′ of FIG. 7A. The second bonding face M3 of the second lid plate 11 and the bonding face M5 of the first crystal frame 30 are bonded to each other by interposing the encapsulating material LG, and the bonding face M4 of the first crystal frame 30 and the bonding face M2 of the second base plate 41 are bonded to each other by interposing the encapsulating material LG. Before the second lid plate 11, the first crystal frame 30, and the second base plate 41 are bonded, the encapsulating material LG having a width wd2 is printed. That is, the encapsulating material LG is not printed on the second lid trench portion 113 and the second base trench portion 413. When the second lid plate 11, the first crystal frame 30, and the second base plate 41 are bonded, they are pressed, and the encapsulating material LG is thinned and widened, so that a part of the widened encapsulating material LG intrudes into the second lid trench portion 113 or the second base trench portion 413.

<Method of Manufacturing Second Crystal Resonator 110>

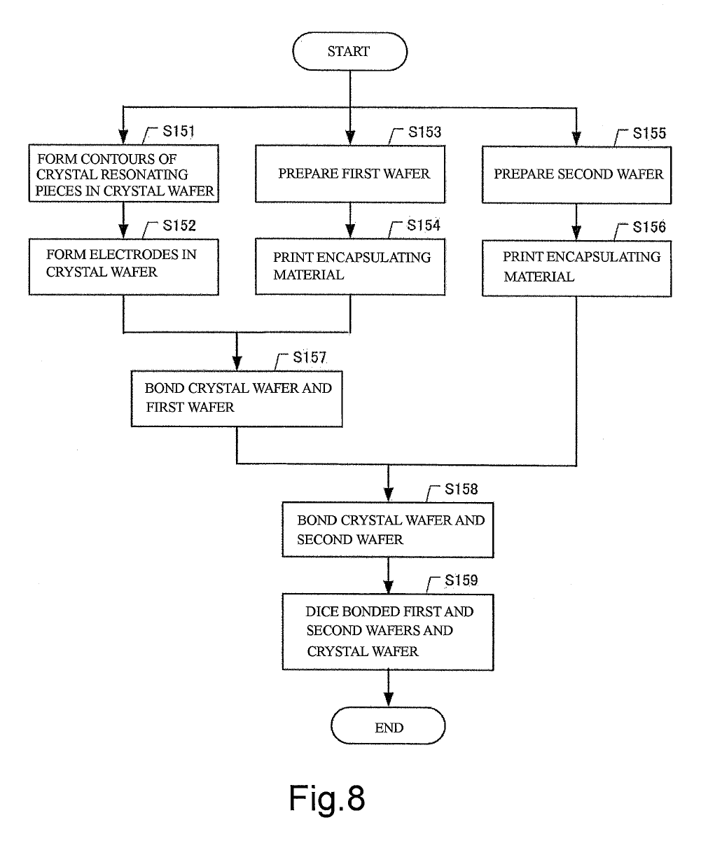

FIG. 8 is a flowchart illustrating a method of manufacturing the second crystal resonator 110.

Step S151 and S152 are substantially similar to steps S101 and S102 of FIG. 2. In the second crystal resonator 110, individual crystal resonating pieces are not cut out from the crystal wafer. Therefore, step corresponding to step S103 of FIG. 2 is not provided. Instead, the first crystal frame 30 formed in step S151 includes a crystal bonding face M4 and a crystal bonding face M5. In addition, the circular through-holes BH1 are formed in four corners of the first crystal frame 30 to penetrate the crystal wafer 30W. Here, a quarter of the circular through-hole corresponds to a castellated portion 306a or 306b (refer to FIG. 7A).

Steps S153 and S155 are substantially similar to steps S104 and S105 of FIG. 2. However, as illustrated in FIGS. 7A and 7B, the second lid plate 11, formed in step S155, has a first lid trench portion 112 and a second lid trench portion 113.

In step S154, the encapsulating material LG is coated on the first bonding face M2 in a ring shape. The encapsulating material LG is coated with a width extending from the scribe line SL to the front of the second base trench portion 413.

In step S156, the encapsulating material LG is coated on the second bonding face M3 in a frame shape. The encapsulating material LG is coated with a width extending from the scribe line SL to the second lid trench portion 113.

In step S157, the crystal bonding face M4 of the crystal wafer and the first bonding face M2 of the first wafer are bonded.

In step S158, the crystal bonding face M5 of the crystal wafer and the second bonding face M3 of the second wafer are bonded. In steps S157 and S158, the encapsulating material LG is pressed and widened thinly. This phenomenon is similar to that of the flowchart of FIG. 5.

### Third Embodiment

### <Entire Configuration of Third Crystal Resonator 120>

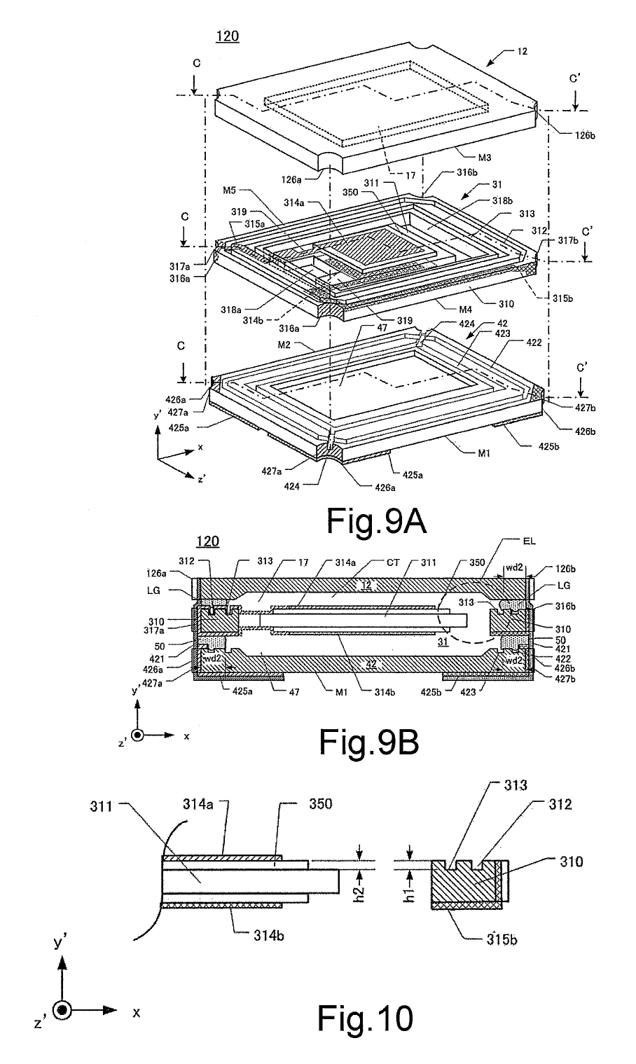

The entire configuration of the third crystal resonator 120 will be described with reference to FIGS. 9A, 9B, and 10.

FIG. 9A is a perspective view illustrating the third crystal resonator 120 in a divided state as seen from the third lid 12 side. FIG. 9B is a cross-sectional view taken along a line C-C′ for illustrating the third crystal resonator 120. FIG. 10 is an enlarged view illustrating the portion EL indicated by a circle in FIG. 9B.

The third crystal resonator 120 is different from the second crystal resonator 110 in that the third crystal resonator 120 has a second crystal frame 31 instead of the first crystal frame 30 of the second crystal resonator 110. In addition, while the third lid 12 does not have the first lid trench portion and the second lid trench portion, the second crystal frame 31 has the first trench portion and the second trench portion. Furthermore, the third base plate 42 has a third base trench portion. In the following description, like reference numerals denote like elements as in the second embodiment, and description thereof will not be repeated. Instead, description will be focused on the difference.

As illustrated in FIG. 9A, the third crystal resonator 120 includes a third lid plate 12 having a lid hollow portion 17, a third base plate 42 having a base hollow portion 47, and an AT-cut second crystal frame 31 placed on the third base plate 42. The third base plate 42 and the third lid plate 12 are made of a crystal material or glass.

The second crystal frame 31 includes an AT-cut rectangular crystal piece 311 and an outer frame 310 surrounding the crystal piece 311. In addition, vertically penetrating gap portions 318a and 318b and a connecting portion 319 are formed between the crystal piece 311 and the outer frame 310.

The second crystal frame 31 is a mesa-structure crystal resonating piece including a vibrating portion (mesa area) 350 thicker than the circumference of the crystal piece 311 in the y′-axis direction and a pair of rectangular excitation electrodes 314a and 314b arranged in both principal faces of the vibrating portion 350. In addition, the lead electrode 315a is connected to the excitation electrode 314a, and the lead electrode 315b is connected to the excitation electrode 314b.

The second crystal frame 31 has a second frame trench portion 313 along the shape of the outer frame in the bonding face M5 of the outer frame 310 and a first frame trench portion 312 at an outer side of the second frame trench portion 313. Castellated portions 316a and 316b are formed in four corners of the second crystal frame 31 by dicing the circular through-hole. Lateral electrodes 317a and 317b are formed in the castellated portions 316a and 316b, respectively.

The third lid plate 12 has the lid hollow portion 17 in the second bonding face M3 in the −y′ side, and castellated portions 126a and 126b are formed in four corners of the third lid plate 12. The castellated portions 126a and 126b are formed by dicing the circular through-hole.

The third base plate 42 has a base hollow portion 47 in the +y′ side and a bonding face M2 formed around the base hollow portion 47. Castellated portions 426a and 426b are formed in four corners of the third base plate 42. Lateral electrodes 427a and 427b are formed in the castellated portions 426a and 426b, respectively.

In the bonding face M2 of the third base plate 42, a second base trench portion 423 and a first base trench portion 422 are formed to surround the base hollow portion 47 in a frame shape. In addition, the third trench portion 424 connects from the second trench portion 423 to the castellated portions 426a and 426b by interposing the first base trench portion 422. In addition, the third base plate 42 has a pair of mounting terminals 415a and 415b electrically connected to the lateral electrodes 417a and 417b, respectively, in the mounting face M1.

Similar to the method of manufacturing the second crystal resonator 110 illustrated in FIG. 8, the third crystal resonator 120 is manufactured by overlappingly bonding three wafers.

In step S157 of FIG. 8, the first wafer and the crystal wafer are heated and pressed in the y′-axis direction. The encapsulating material LG is interposed between the first wafer and the crystal wafer, intrudes into the first base trench portion 422, and is widened on the bonding face M2. Out of the widened encapsulating material LG, a part of the encapsulating material LG widened to the cavity CT side enters the second trench portion 423. The third trench portion 424 is connected to the first trench portion 422 and the second trench portion 423. For this reason, even when an excess encapsulating material LG is printed, the excess encapsulating material LG flows out to the castellated portion 426 through the third trench portion 424. The third trench portion 424 can suppress the excess encapsulating material LG from entering the inside of the cavity CT.

According to the third embodiment of the disclosure, in order to ensure conduction between wafers, the following process is added between step S158 and step S159 of FIG. 8.

As illustrated in FIG. 9B, the third lid plate 12, the second crystal frame 31, and the third base plate 42 are bonded using the encapsulating material LG. Then, a ceiling surface of the lid and the mounting face M1 are masked excluding the mounting terminal 425, and sputtering or vacuum deposition is performed for the wafer. Then, a lateral connecting electrode 421 is formed in the circular through-hole BH1 through sputtering, and the lateral electrode 317 of the second crystal frame 31 and the base lateral electrode 427 are connected, so that the lead electrode 315 is electrically bonded to the mounting terminal 425.

<Manufacturing of First Frame Trench Portion and Second Frame Trench Portion>

FIG. 10 is an enlarged view illustrating the portion EL indicated by a circle of FIG. 9B, that is, a part of the second crystal frame 31. Since the crystal piece 311 has a mesa structure, a thickness difference h2 exists between the vibrating portion 350 and the circumference of the crystal piece 311. The thickness difference h2 is formed through wet etching. The first frame trench portion 312 and the second frame trench portion 313 are formed in the outer frame 310 through wet etching. If the depths h1 of the second frame trench portion 313 and the first frame trench portion 312 are substantially equal to the thickness difference h2, it is possible to form the first frame trench portion 312 and the second frame trench portion 313 when the circumference of the crystal piece 311 lower than the vibrating portion 350 is formed.

### Fourth Embodiment

### <Entire Configuration of Fourth Crystal Resonator 130>

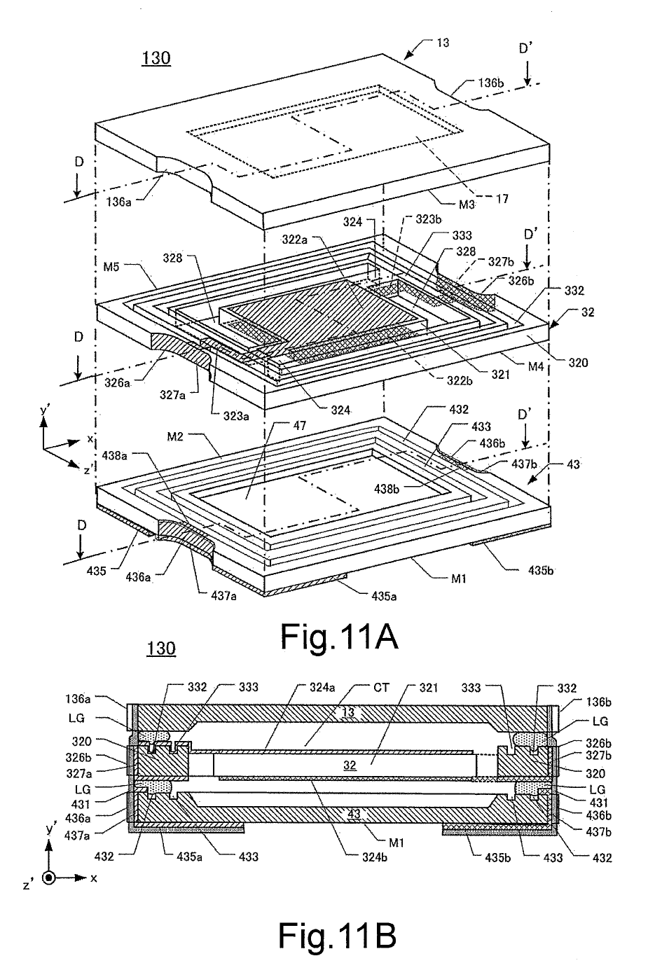

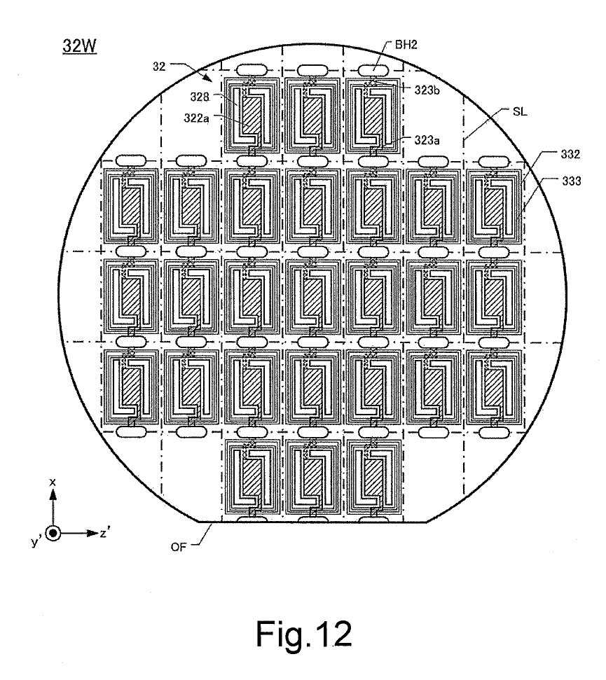

The entire configuration of the fourth crystal resonator 130 will be described with reference to FIGS. 11A, 11B, and 12. FIG. 11A is an exploded perspective view illustrating the fourth crystal resonator 130. FIG. 11B is a cross-sectional view taken along a line D-D′ for illustrating the fourth crystal resonator 130. FIG. 12 is a top plan view illustrating the crystal wafer W32 of the fourth crystal resonator 130.

The fourth crystal resonator 130 is different from the third crystal resonator 120 in that a third crystal frame 32 is mounted on a fourth base plate 43 instead of the second crystal frame 31. In addition, a position and a shape of the castellated portion are different. In the following description, like reference numerals denote like elements as in the third embodiment, and description thereof will not be repeated. Instead, description will be focused on the difference.

As illustrated in FIGS. 11A and 11B the fourth crystal resonator 130 includes a fourth lid plate 13 having a lid hollow portion 17, a fourth base plate 43 having a base hollow portion 47, and a third crystal frame 32 placed on the fourth base plate 43.

The third crystal frame 32 has a crystal bonding face M4 and a crystal bonding face M5. The third crystal frame 32 has an outer frame 320 surrounding the crystal resonating portion 321. A vertically penetrating L-shaped gap portion 328 is formed between the crystal resonating portion 321 and the outer frame 320, so that a portion where the gap portion 308 is not formed corresponds to the connecting portion 324 between the crystal resonating portion 321 and the outer frame 320.

The excitation electrodes 322a and 322b are oppositely arranged in both principal faces in the vicinity of the center of the crystal resonating portion 321. The excitation electrode 322a is connected to the lead electrode 323a extending up to the −x side of the surface (+y′ side) of the crystal resonating portion 321, and the excitation electrode 322b is connected to the lead electrode 323b extending up to the +x side of the bottom face (−y′ side) of the crystal resonating portion 321.

In the outer frame 320 of the third crystal frame 32, the second frame trench portion 333 is formed along the gap portion 308 in the crystal bonding face M5, and the first frame trench portion 332 is formed in the outer side of the second frame trench portion 333. In the third crystal frame 32, castellated portions 326a and 326b extending in the z′-axis direction are formed in both sides of the x-axis direction. The castellated portions 326a and 326b are formed by dicing the corner-rounded rectangular through-hole BH2 (refer to FIG. 12). The lateral electrodes 327a and 327b are formed in the castellated portions 326a and 326b, respectively.

The fourth base plate 43 has the bonding face M2 formed around the base hollow portion 47 on the surface (+y′ side face). In the fourth base plate 43, the castellated portions 436a and 436b extending in the z′-axis direction are formed in both sides in the x-axis direction. The lateral electrodes 437a and 437b are formed in the castellated portions 436a and 436b, respectively. The fourth base plate 43 has a pair of mounting terminals 435, 435a, and 435b electrically connected to the lateral electrodes 437a and 437b, respectively, in the mounting face M1.

The fourth lid plate 13 has a lid hollow portion 17 in the second bonding face M3 of the −y′ side. In the fourth lid plate 13, castellated portions 136a and 136b extending in the z′-axis direction are formed in both sides in the x-axis direction. The castellated portions 136a and 136b are formed by dicing the corner-rounded rectangular through-hole by a half.

The fourth lid plate 13, the third crystal frame 32, and the fourth base plate 43 are bonded using the encapsulating material LG, and then, they are sputtered by masking the base side and the lid side excluding the mounting terminal 435. Then, a lateral connecting electrode 432 is formed in the corner-rounded rectangular through-hole BH2 through sputtering, and the lateral electrode 327 of the third crystal frame 32 and the base lateral electrode 437 are conducted, so that the lead electrode 323 and the mounting terminal 435 are electrically bonded.

In the crystal resonator described above, the first plate may be a base plate having an external electrode on the first face, the second plate may be a piezoelectric vibrating piece having an excitation portion where an excitation electrode is formed and a frame surrounding the excitation portion, and the base plate and the frame may be bonded using the bonding material.

In the crystal resonator described above, the excitation portion may have a mesa area where the excitation electrode is formed and a circumference area which is formed around the mesa area and has a thickness smaller than that of the mesa area, and a depth of the first trench portion may be substantially equal to a difference between the mesa area and the circumference area.

In the crystal resonator described above, the first plate may be a base plate having an external electrode on the first face, the second plate may be a lid plate that covers an excitation portion having an excitation electrode, and the base plate and the lid plate may be bonded using the bonding material.

The crystal resonator described above may further include a castellated portion formed in a side face that connects the first and second faces; and a lateral electrode formed in the castellated portion, and the external electrode and the lateral electrode may be electrically connected.

The crystal resonator according to this disclosure is capable of suppressing the encapsulating material from entering the cavity and enhancing the bonding strength between the first and second plates.

While best modes or embodiments of the invention have been described in detail hereinbefore, those skilled in the art will be appreciated that variations and changes may be made without departing from the scope or spirit of the present invention.

Although the lid plate portion, the crystal frame, and the base plate are bonded using low-melting glass LG as a nonconductive adhesive according to the first to fourth embodiments of the disclosure, polyimide resin may be used instead of the low-melting glass. The crystal resonating piece according to the first to fourth embodiments of the disclosure may be basically applied to a piezoelectric material including lithium tantalite, lithium niobate, or piezoelectric ceramic as well as the crystal material. Furthermore, the crystal resonating piece according to the first to fourth embodiments of the disclosure may be applied to a piezoelectric generator having an oscillation circuit such as an integrated circuit (IC) for oscillating the piezoelectric vibrating piece.

What is claimed is:

1. A crystal resonator comprising:
a first plate, having a first face and a second face opposite to the first face;
a second plate, having a third face and a fourth face opposite to the third face;
a bonding material, arranged in a ring shape between the second face of the first plate and the third face of the second plate to bond the first plate and the second plate;
a first trench portion, where the bonding material intrudes along a ring shape of the bonding material, on at least one of the second or third face; and
a second trench portion, formed side by side with the first trench portion at an inner side of the ring shape of the bonding material on at least one of the second face or the third face.

2. A crystal resonator comprising:
a first plate, having a first face and a second face opposite to the first face;
a second plate, having a third face and a fourth face opposite to the third face;
a bonding material, arranged in a ring shape between the second face of the first plate and the third face of the second plate to bond the first plate and the second plate;
a first trench portion, where the bonding material intrudes along a ring shape of the bonding material, on at least one of the second or third face;
at least a pair of castellated portions, formed at a corner of at least one of the first or second plate; and
a third trench portion, connecting from the first trench portion to the castellated portion.

3. The crystal resonator according to claim 1, wherein,
the first plate is a base plate having an external electrode on the first face,
the second plate is a piezoelectric vibrating piece having an excitation portion where an excitation electrode is formed and a frame surrounding the excitation portion, and
the base plate and the frame are bonded using the bonding material.

4. The crystal resonator according to claim 3, wherein,
the excitation portion has a mesa area where the excitation electrode is formed, and a circumference area which is formed around the mesa area and has a thickness smaller than that of the mesa area, and
a depth of the first trench portion is substantially equal to a thickness difference between the mesa area and the circumference area.

5. The crystal resonator according to claim 1, wherein,
the first plate is a base plate having an external electrode on the first face,
the second plate is a lid plate that covers an excitation portion having an excitation electrode, and
the base plate and the lid plate are bonded using the bonding material.

6. The crystal resonator according to claim 3, further comprising:
a castellated portion, formed in a side face that connects the first face and second face; and
a lateral electrode, formed in the castellated portion,
wherein, the external electrode and the lateral electrode are electrically connected.
